(19) United States
(12) Patent Application Publication
(10) Pub. No.: US 2005/0057149 A1
(43) Pub. Date: Mar. 17, 2005

(54) Method for manufacturing display; electronic device and display element

(75) Inventors: Timo Herranen, Viiala (FI); Esa Maatta, Viiala (FI)

Correspondence Address: Crawford Maunu PLLC, Suite 390, 1270 Northland Drive, St. Paul, MN, 55120, US

(73) Assignee: Nokia Corporation

(21) Appl. No.: 10/929,661

(22) Filed: Aug. 30, 2004

(30) Foreign Application Priority Data
Sep. 3, 2003 (FI) 20031251

(51) Int. Cl. H01J 1/62

(52) U.S. Cl. 313/504

(57) ABSTRACT

A method for manufacturing an electronic device; an electronic device and a display element. The device comprises at least a first and a second display, the displays being OLED displays arranged on opposite sides of one and the same part of the device, the first display showing information mainly in a first direction and the second display, correspondingly, mainly in a second direction substantially opposite from the first direction. The first and the second display are arranged such that the second display forms at least a part of the structure protecting the back of the first display.

### BACKGROUND OF THE INVENTION

The invention relates to a method for manufacturing an electronic device comprising at least a first and a second display, the displays being arranged on opposite sides of a part belonging to the device such that the displays show information in substantially opposite directions.

The invention further relates to an electronic device comprising at least a first and a second display arranged on opposite sides of one and the same part belonging to the device, the first display showing information mainly in a first direction and the second display, correspondingly, mainly in a second direction substantially opposite from the first direction.

The invention still further relates to a double-sided display element arranged to display visual information in a first direction and in a second direction substantially opposite from the first direction.

Prior art knows electronic hand-held devices that have two displays for displaying visual information to a user. In this context, ‘hand-held devices’ refer to mobile phones, communicators, other PDA (Personal Digital Assistant) devices and similar devices the special characteristics of which include low weight and small size. Hereinafter such hand-held devices will be referred to in this specification as “devices”.

Two displays make a device more versatile and easier to use. The displays are typically arranged to the device such that the information they show can be read from different sides of the device. It is also typical that the displays can be used for showing information independently of one another. For example, one of the displays may be used for showing names and telephone numbers needed in telephone use, whereas the other display—often larger than the former—can be used for word processing. In a two-part device, such as a communicator or what is known as a flip-top mobile phone, where the parts of the device can be turned against each other to a closed position and, correspondingly, away from each other to an open position, in the closed position there is most often only a smaller display available. The larger display is taken in use by turning the parts of the device away from each other.

The displays of the devices are most often based on the following techniques: LCD (Liquid Crystal Display), such as LCD-TFT (LCD-Thin Film Transistor), and OLED (Organic Light Emitting Diode), although other display types that can be expected to become more popular in the future are also known, such as FED (Field Effect Display).

There are some problems in providing a device with two displays. Two displays occupy a relatively large space, particularly in view of the space needed by other components of the device. Especially when the displays are to be arranged on opposite sides of one and the same part of the device, this part becomes fairly thick. Two displays also make the device heavier, and they are clearly contradictory to the aim of keeping the size and weight of the device as small as possible.

### BRIEF DESCRIPTION OF THE INVENTION

It is therefore an object of the present invention to provide a novel method for manufacturing a display, an electronic device, and a display element such that a thinner and lighter display construction is achieved than in prior art solutions.

The method of the invention is characterized in that the displays are OLED displays and that the second display is arranged in connection with the first display such that it forms at least a part of a structure protecting the back of the first display.

Further, the electronic device of the invention is characterized in that the displays are OLED displays arranged such that the second display forms at least a part of a structure protecting the back of the first display.

Further still, the double-sided display element of the invention is characterized in that the display element comprises a first and a second display, which are arranged such that the second display forms at least a part of a structure protecting the back of the first display.

The basic idea of the invention is that two OLED displays are integrated back to back so that both of them form at least a part of the structure protecting the other one's back.

An advantage of the invention is that since the displays protect each other, the number of protective structures between them can be reduced and they can be made thinner, whereby the construction of the displays becomes thinner than in a solution based on two ordinary displays. A further advantage is that an integrated display construction is lighter than two ordinary displays. Yet another advantage is that the invention does not affect the quality of the information displayed.

A still further advantage is that the structure of a double-sided OLED display is particularly thin, because the means required for creating visual information are extremely thin and because separate lighting elements, for example, are not needed.

An essential idea of a preferred embodiment of the invention is that the displays are formed into an assembly module, the advantage of which is that it facilitates and speeds up the final assembly of the device.

### BRIEF DESCRIPTION OF THE FIGURES

The invention will be discussed in greater detail with reference to the following figures, in which

FIG. 1 is a schematic, partly sectional perspective view of a prior art double-sided display construction;

FIG. 2 is a schematic, partly sectional perspective view of a double-sided display element of the invention;

FIG. 3a is schematic perspective view of a part of the electronic device of the invention as seen from a first direction; and

FIG. 3b is a schematic perspective view of the part of the electronic device of FIG. 3a as seen from a second direction.

For the sake of clarity the invention is illustrated in a simplified form in the figures. Like parts are indicated with like reference numerals.

### DETAILED DESCRIPTION OF THE INVENTION

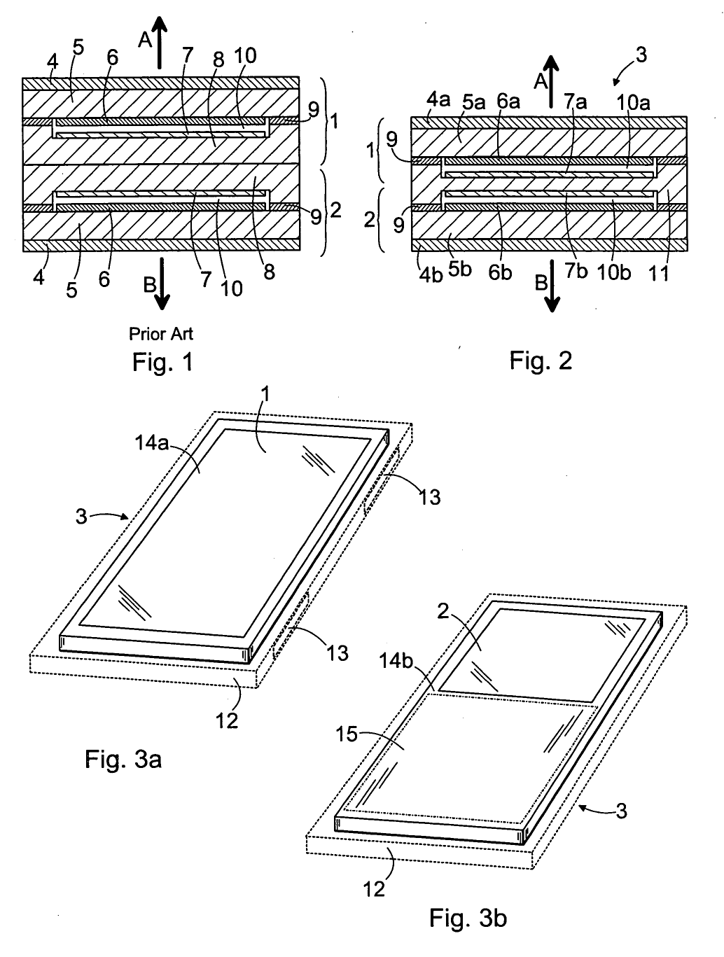

FIG. 1 is a schematic, partly sectional perspective view of a double-sided prior art display construction. A first display 1 and a second display 2 are superimposed back to back and attached to each other. Thus the space required by the displays 1, 2 is as small as possible in the direction of thickness. In this context the back of the display refers to the display surface that is on the side of the display that faces away from the display surface showing visual information.

In the Figure the first display 1 shows information in an upward direction, i.e. mainly in the direction shown by arrow A, and the second display 2, correspondingly, in a downward direction, i.e. mainly in the direction shown by arrow B.

The displays 1, 2 are both OLED (Organic Light Emitting Diode) type display elements. From the outside inwards, each display 1, 2 comprises: polarizer 4, basic layer 5, emission layer 6, moisture absorbing layer 7, and a protective back element 8.

The actual visual information to be displayed on display 1, 2 is created in the emission layer 6. The emission layer 6 is formed on the surface of the basic layer 5. On the other side of the basic layer 5, opposite to the emission layer 6, there is arranged a polarizer 4, which reduces reflections caused by ambient light and, at the same time, serves as the outermost layer of the display 1, 2.

Underneath the emission layer 6 there is arranged humidity absorbing material 7, such as silica gel, and the protective back element 8. These layers protect the emission layer 6 against humidity, among other things. This is essential for the operation of the OLED display, because the organic emissive material in the emission layer 6 is destroyed by oxidation if it gets into contact with humidity. In addition, the protective back element 8 provides mechanical protection for the display 1, 2. The protective element 8 is made of glass, for example. The protective back element 8 is provided with a depression or a recess where the humidity absorbing material 7 is arranged such that a gas space 10 is left between the material and the emission layer 6.

The protective element 8 is attached to the basic layer 5 at its edge portions by means of an attachment layer 9.

FIG. 2 is a schematic, partly sectional perspective view of a double-sided display element of the invention. The display element 3 comprises two OLED type displays: a first display 1 and a second display 2. The active display surfaces of the displays 1, 2, i.e. the display surfaces showing visual information, are of the same size and shape. Since the displays 1, 2 are arranged back to back, the display element is capable of showing information in two opposite directions, primarily in those of arrows A and B indicating an upward and a downward direction in the Figure. The display element 3 forms an assembly module and therefore the displays 1, 2 can be fitted simultaneously and rapidly in place into the device. The assembly module thus simplifies and speeds up the final assembly of the device.

In FIG. 2 the outer layers of the display element 3 are formed by polarizers 4a, 4b. However, the polarizers 4a, 4b are not indispensable and can be left out from the display element 3 construction, if desired.

Underneath the polarizers 4a, 4b there are basic layers 5a, 5b, which are made of a suitably transparent material, such as glass.

Both of the basic layers 5a, 5b have an emission layer 6a, 6b attached thereto, the emission layer including thin layers that comprise an organic, emissive material and electrical conductors or electrodes arranged on both sides of the layers. The organic, emissive material is typically a natural or a synthetic polymer, such as protein or DNA. The bottommost electrode in the emission layer 6a, 6b may be made of a material that reflects visible light.

When electric current is switched on between the electrodes, the organic, emissive material emits visible light. The phenomenon is typically based on electro-luminescence, which is known per se to a person skilled in the art and therefore not discussed in greater detail in this context.

Despite its layered structure, the emission layer 6a, 6b is very thin, typically less than 0.5 mm. Since the OLED display itself emits visible light, a separate lighting element, such as a backlight, is not needed. The energy consumption of the OLED is thus extremely low. In addition, an advantage of the OLED type display that can be mentioned is its wide viewing angle.

The OLED structure of the displays 1, 2 may be passive or active. In an active OLED, a TFT (Thin Film Transistor) matrix, for example, can be used to control the pixels of the display 1, 2. The TFT matrix would be located in the emission layer 6a, 6b of the display 1, 2.

The emission layer 6a, 6b may be implemented as a structure known as a bottom emitting structure, in which case it comprises a reflective cathode and a transparent anode. The emitting light exits from the emission layer 6 through the transparent anode. The displays 1, 2 of FIG. 2 both have this kind of structure. The emission layer 6a, 6b may also be implemented as a structure known as a top emitting structure having a semi-transparent cathode and a reflective anode. However, there are also other ways of implementing the emission layer 6a, 6b.

The displays 1, 2 and their structures may naturally be based on structures differing from one another; for example, the first display 1 may have a bottom emitting structure and the second display 2 a top emitting structure.

In the embodiment shown in the Figure the emission layer 6a, 6b is formed on the surface of the corresponding basic layer 5a, 5b. The basic layer 5a, 5b is made of at least partly transparent material, such as glass suitable for the purpose and known per se. The light emitted by the emission layer 6a, 6b proceeds through the corresponding basic layer 5a, 5b and the polarizer 4a, 4b and out of the display 1, 2.

The displays 1, 2 are integrated back to back, and they have a common encapsulation element 11. On either surface of the encapsulation element 11 there is a recess with a moisture absorbing material 7a, 7b, such as silica gel or the like, arranged therein.

The emission layer 6a, 6b is arranged into a closed space formed by the encapsulation element 11 and the basic layers 5a, 5b such that a gas space 10a, 10b is left between the emission layer 6a, 6b and the moisture absorbing layer 7a, 7b. The gas space 10a, 10b typically contains air. The moisture absorbing material 7a, 7b absorbs moisture possibly appearing in the gas space 10a, 10b. There are naturally also other ways of positioning the moisture absorbing layer 7a, 7b so that it is connected to the corresponding gas space 10a, 10b.

The encapsulation element 11 is attached at its edge portions both to the basic layer 5 of the first display and the corresponding basic layer 5b of the second display. The layers are attached by means of the attachment layer 9, which may be a layer of glue or a double-sided adhesive tape, for example.

The first display 1 may be used for showing information that is fully independent of the information shown on the second display 2, and vice versa.

FIG. 3a shows a schematic perspective view of a part of the electronic device of the invention as seen from a first direction and FIG. 3b as seen from a second direction. The device part 12 in question belongs to an electronic device consisting of several parts, such as a communicator or a mobile phone, which has parts that can be turned in relation to each other. For the sake of simplicity, the Figure only shows the device part 12 comprising displays 1, 2, which part can be arranged in a preferably turnable manner to the rest of the device by means of attachment members 13. The attachment members 13 can be implemented in manners known per se and therefore their implementation will not be discussed in greater detail in this context. The part 12 of the device and its attachment members 13 are shown with a dashed line in FIG. 2.

The device part 12 is provided with a double-sided display element 3 arranged thereto, the first display 1 of the element being arranged on a first side of the device part 12 and the second display 2, correspondingly, on a second side of the part 12. At the same time the display element 3 forms an assembly module that is handled as a single component during the final assembly of the device. The active display surface of the first display 1 is substantially greater than the corresponding surface of the second display 2. The first display 1 is excellent for example for word processing, spreadsheet computation, processing of still or video pictures and for similar processing. The second display 2 is suitable for example for displaying information relating to the telephone use or for use as a finder of a camera possibly belonging to the device or attachable to it. Naturally the displays 1, 2 may have other purposes of use as well.

The displays 1, 2 have protective elements 14a, 14b arranged as their outer layers. The basic layer 5a, 5b or the polarizer 4a, 4b shown in FIG. 2 may serve as a protective element 14a, 14b, but in any case the protective elements 14a, 14b are transparent at least at the active display surface of the displays 1, 2. The protective elements 14a, 14b protect the displays 1, 2 against damages that might be caused by environmental elements.

The protective elements 14a, 14b form a protected space between them, the two displays 1, 2 facing away from each other being arranged thereto. The protective element 14a of the first display 1 protects not only the first but also the back of the second display 2 and, correspondingly, the protective element 14b of the second display 2 also protects the back of the first display 1. This has made it possible to provide thinner and lighter protective structures on the backs of the displays 1, 2 and to thereby achieve an extremely compact, thin and light structure.

Naturally the displays 1, 2 can be further protected by an additional protective window or a similar transparent protective layer known per se, which is typically attached to the cover of the device.

Adjacent to the second display 2 there remains a space 15 that can be utilized in various ways, for example by arranging the keys used for operating the device thereto.

A display element 3 having two displays of different sizes can also be implemented such that the first display 1, i.e. the larger one, protects the entire back surface of the second, smaller, display 2, whereas the second display 2 only protects a part of the back surface of the first display 1. In that case the portion of the back of the first display 1 that is not against the second display 2 is protected by a protective layer conventionally used for the display type in question.

The drawings and the related specification are only meant to illustrate the inventive idea. The details of the invention may vary within the scope of the claims. Consequently, one of the displays 1, 2, or both of them, may be configured to operate as a touch screen. The displays may be grey scale or colour displays. The basic structure of the double-sided, top-emitting display element can be implemented for example by arranging the emission layers 6a, 6b on opposite surfaces of the encapsulation element 11. This allows the basic layers 5a, 5b to be left out and the polarizers 4a, 4b to be fixed directly to the encapsulation element 11. The emission layer 6a, 6b is in the space between the polarizer and the encapsulation element 11, isolated from the environment.

1. A method for manufacturing an electronic device comprising at least a first and a second display, the displays being arranged on opposite sides of a part belonging to the device such that the displays show information in substantially opposite directions, wherein the displays are OLED displays and that the second display is arranged in connection with the first display such that it forms at least a part of a structure protecting the back of the first display.

2. A method according to claim 1, further using the first and the second display to form a display element, which is mounted to the device as a single entity.

3. A method according to claim 1, wherein the displays are attached to each other by means of an encapsulation element shared by the displays.

4. An electronic device comprising at least a first and a second display arranged on opposite sides of one and the same part belonging to the device, the first display showing information mainly in a first direction and the second display, correspondingly, mainly in a second direction substantially opposite from the first direction, wherein the displays are OLED displays arranged such that the second display forms at least a part of a structure protecting the back of the first display.

5. A device according to claim 4, wherein the first and the second display are arranged to form a single double-sided display element serving, at the same time as an assembly module.

6. A device according to claim 4, wherein the display surfaces of the displays are substantially of the same size and shape.

7. A device according to claim 4, wherein the display surfaces of the displays are substantially different in size.

8. A device according to claim 4, wherein the displays are configured to show information independently from each other.

9. A device according to claim 4, wherein the device is a mobile phone or a communicator.

10. A double-sided display element arranged to display visual information in a first direction and in a second direction substantially opposite from the first direction, wherein the display element comprises a first and a second display, the displays being OLED displays arranged such that the second display forms at least a part of a structure protecting the back of the first display.

11. A display element according to claim 10, wherein the display surfaces of the displays are substantially of the same size and shape.

12. A display element according to claim 10, wherein the display surfaces of the displays are substantially different in size.

13. A display element according to claim 10, wherein the displays are arranged to show information independently from one another.
